(19) United States
(12) Patent Application Publication
(10) Pub. No.: US 2008/0223433 A1
(43) Pub. Date: Sep. 18, 2008

(54) Solar Module with a Stiffening Layer

(75) Inventors: Jack I. Hanoka, Brookline, MA (US); Joseph Woods, Chicopee, MA (US)

Correspondence Address: BROMBERG & SUNSTEIN LLP, 125 SUMMER STREET, BOSTON, MA, 02110-1618, US

(73) Assignee: EVERGREEN SOLAR, INC., Marlborough, MA (US)

(21) Appl. No.: 12/048,692

(22) Filed: Mar. 14, 2008

Related U.S. Application Data
(60) Provisional application No. 60/906,880, filed on Mar. 14, 2007.

(51) Int. Cl. H01L 31/048; H01L 31/18

(52) U.S. Cl. 136/251; 427/74

(57) ABSTRACT

A solar module includes a plurality of interconnected photovoltaic cells, an encapsulant layer encapsulating the photovoltaic cells, the encapsulant layer having a first side, a protective layer coupled to the first side of the encapsulant layer, and a stiffening layer coupled to the protective layer, the stiffening layer having an open support structure that provides stiffness to the solar module.

### CROSS-REFERENCE TO RELATED APPLICATIONS

This patent application claims priority to U.S. Provisional Patent Application No. 60/906,880 filed Mar. 14, 2007, entitled METHOD AND DEVICE FOR STIFFENING A PHOTOVOLTAIC MODULE, the disclosure of which is incorporated by reference herein in its entirety.

### FIELD OF THE INVENTION

The invention generally relates to solar modules and, more particularly, the invention relates to solar modules with a stiffening layer to reduce the amount of flexing of the modules.

### BACKGROUND OF THE INVENTION

A conventional design for solar modules, particularly those made with crystalline silicon photovoltaic cells, typically includes a thermally tempered glass superstrate, a layer of a transparent encapsulant material adjacent to the superstrate, interconnected photovoltaic cells, another layer of encapsulant material encapsulating the photovoltaic cells, a polymeric protective backsheet, and a frame of aluminum secured at the perimeter of the layers. In addition, a strip or gasket may be applied between the perimeter frame and the edge of the tempered glass as a cushion layer to protect the glass from shattering due to an edge impact. The perimeter frame functions to protect edges of the tempered glass superstrate, to provide for some level of stiffness for the module, and to allow for mounting onto other structures, such as a rack attached to a roof or other surface.

Current trends in crystalline silicon solar modules include an increase in module size and use of thinner crystalline silicon wafers. Larger modules and/or thinner wafers may result in the module flexing too much, causing the solar cells to unacceptably crack. To reduce the amount of flexing the module sustains, a thicker glass superstrate and/or a heavier perimeter frame may be used. Both of these solutions, however, increase the cost and weight of larger solar modules. Also, there is a limit as to how much stiffness the perimeter frame can provide to the module since the support is only on the edges of the module.

### SUMMARY OF THE INVENTION

In accordance with one embodiment of the invention, a solar module includes a plurality of interconnected photovoltaic cells, an encapsulant layer encapsulating the photovoltaic cells and having a first side, a protective layer coupled to the first side of the encapsulant layer, and a stiffening layer coupled to the protective layer. The stiffening layer has an open support structure that provides stiffness to the solar module.

In accordance with related embodiments, the open support structure may include a corrugated structure. Among other things, the corrugated structure may be a sinusoidal wave shape, a square wave shape, or a trapezoidal wave shape. The open support structure may include a geometrical structure, such as a honeycomb structure. The open support structure may be formed from a metal, a metal alloy, or a polymer. The module may further include a transparent superstrate adjacent to a second side of the encapsulant layer. For supporting the solar module, the module may further include a frame disposed at the perimeter of the underlying apparatus, which includes photovoltaic cells, the encapsulant layer, the protective layer and the stiffening layer. The stiffening layer may include a support layer on at least one side of the open support structure. The support layer may be formed from a metal or metal alloy. The stiffening layer may include one or more openings formed therein.

In accordance with another embodiment of the invention, a method of producing a solar module includes providing a plurality of interconnected photovoltaic cells in an encapsulant layer having a first side, forming a protective layer on the first side of the encapsulant layer, and forming a stiffening layer on the protective layer. The stiffening layer has an open support structure that provides stiffness to the solar module.

In accordance with another embodiment of the invention, a solar module includes a plurality of interconnected photovoltaic cells, an encapsulant layer encapsulating the photovoltaic cells and having a first side, and a stiffening layer coupled to the first side of the encapsulant layer. The stiffening layer has an open support structure that provides stiffness to the solar module.

### BRIEF DESCRIPTION OF THE DRAWINGS

The foregoing and advantages of the invention will be appreciated more fully from the following further description thereof with reference to the accompanying drawings wherein:

FIG. 1 schematically shows solar modules mounted on a roof according to embodiments of the present invention;

FIG. 2 schematically shows a cross-sectional view of an exemplary solar module according to embodiments of the present invention;

FIG. 3 schematically shows a cross-sectional view of an exemplary solar module with support layers on either side of a stiffening layer according to embodiments of the present invention;

FIG. 4 schematically shows a cross-sectional view of an exemplary solar module having a protective layer and superstrate according to embodiments of the present invention;

FIG. 5 schematically shows a cross-sectional view of an exemplary solar module having a protective layer and support layers on either side of a stiffening layer according to embodiments of the present invention;

FIG. 6 schematically shows a perspective view of a solar module with a stiffening layer having openings formed therein according to embodiments of the present invention; and

FIG. 7 shows a process of forming a solar module with a stiffening layer according to embodiments of the present invention.

### DESCRIPTION OF ILLUSTRATIVE EMBODIMENTS

Embodiments of the present invention provide a solar module with a stiffening layer having an open support structure that provides stiffness to the module while minimizing the weight the stiffening layer adds to the module. The open support structure may include a corrugated structure or a geometrical structure (e.g., a honeycomb structure), which may be made of a metal, a metal alloy, or a polymer material. The stiffening layer provides support to the module, such as across the middle of the module, in order to reduce the amount of flexing the module sustains. In some embodiments, the glass superstrate and/or the perimeter frame may be eliminated altogether. Details of illustrative embodiments are discussed below.

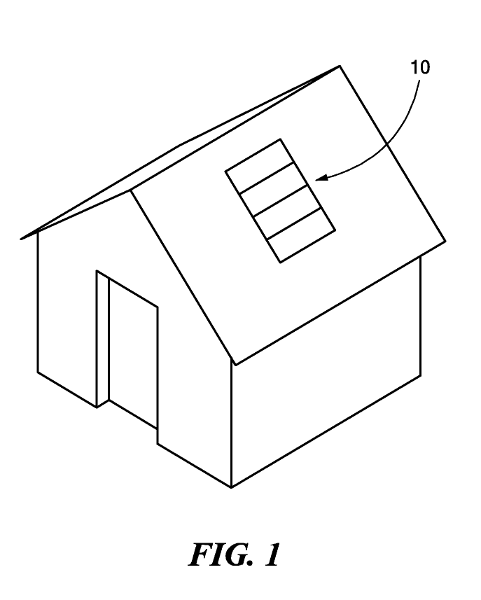

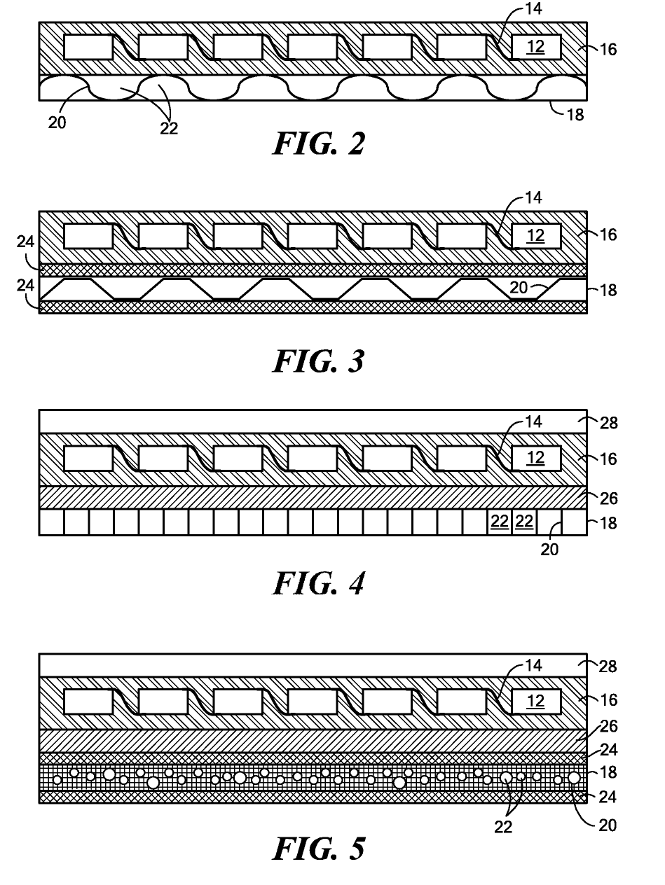

FIG. 1 schematically shows an array of solar modules 10 produced according to embodiments of the present invention. The array may be mounted on a roof or other surface as is well known to those skilled in the art. FIG. 2 schematically shows a cross-sectional view of an exemplary solar module according to illustrative embodiments of the present invention. The solar module may include a plurality of photovoltaic cells 12, interconnected by leads 14 and encapsulated in an encapsulant layer 16 and a stiffening layer 18 coupled to one side of the encapsulant layer 16. The photovoltaic cells 12 may be arranged in a row and connected in series, as shown, or have other configurations. The encapsulant layer 16 may include one or more transparent layers and may provide protection for the photovoltaic cells 12 and leads 14. Examples of some encapsulant materials are described in U.S. Pat. No. 6,114,046.

In accordance with illustrative embodiments of the invention, the stiffening layer 18 has an open support structure 20 that provides stiffness to the solar module while minimizing module weight. To accomplish this, the open support structure 20 forms open areas 22 in the stiffening layer 18. The combination of the open support structure 20 and the open areas 22 allows the weight of the stiffening layer 18 to be reduced compared to a solid planar sheet or film of the material with the same stiffness properties.

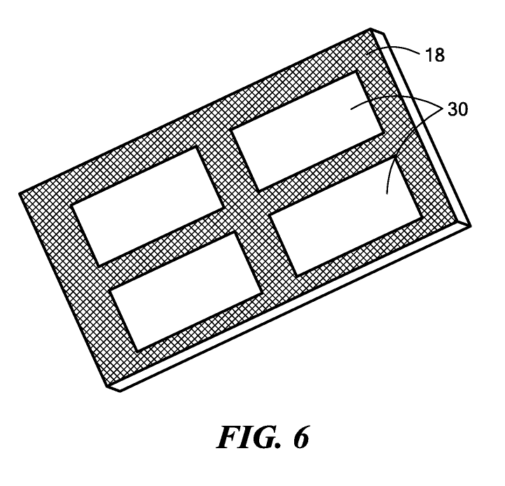

The open support structure 20 may have a variety of configurations. For example, the open support structure 20 may include a corrugated structure having any shape that can be adapted for this application, such as a sinusoidal wave shape (e.g., as shown in FIG. 2), a square wave shape, a trapezoidal wave shape (e.g., as shown in FIG. 3), etc. The open support structure 20 may include a geometrical structure having a repeating pattern of open or closed cells adjacent to one another (e.g., as shown in FIG. 4). The cells in the geometrical structure may have any shape, such as a polygonal shape (e.g., a triangular shape, a square shape, a hexagonal or honeycomb shape, etc.) or a curved shape (e.g., a circular shape, elliptical shape, etc.). The open support structure 20 may include a material, such as a polymer material (e.g., a resin), that forms the open areas 22 within the material (e.g., as shown in FIG. 5).

As shown in FIG. 5, the open support structure 22 may form open areas 22 that are entirely within the stiffening layer 18. Such areas are not exposed to any surface or component exterior to the stiffening layer 18. Alternatively, some embodiments may form some open areas 22 that are entirely within the stiffening layer 18, and other open areas 22 that are exposed to one of the surfaces of the stiffening layer 18 (e.g., as shown in FIGS. 2-4). In any event, illustrative embodiments form the open areas 22 such that the open areas 22 are macroscopic in size in relation to the layer 18 or on the order of the thickness of the layer 18.

Preferably, the open areas 22 comprise a certain amount or percentage of the stiffening layer 18 so that the stiffening layer 18 provides an adequate stiffness to the module without adding unnecessary weight. For example, the open areas 22 may comprise about 30% or more of the volume of the stiffening layer 18.

As shown in FIG. 3, the stiffening layer 18 may include a support layer 24 on one or both sides of the open support structure 20. The open support structure 20 and the support layer(s) 24 may be formed of any of a number of materials, such as a metal, a metal alloy or a polymer material. The open support structure 20 and the support layer(s) 24 may be formed of the same or different materials. For example, the open support structure 20 and/or the support layer(s) 24 may be formed of aluminum. As another example, the open support structure 20 may be formed of a polymer material and the support layer(s) 24 may be made of thin sheets of aluminum. The open support structure 20 and the support layer(s) 24 may have any of a number of different thicknesses, which may vary depending on the materials used. For example, the open support structure 20 may have a thickness of about 2 mm to about 50 mm and the support layer(s) 24 may have a thickness of about 0.5 mm to about 2 mm. When a support layer 24 is formed between the stiffening layer 18 and the encapsulant layer 16, the support layer 24 is coupled to one side of the encapsulant layer 16.

Some embodiments of the present invention may include one or more additional layers coupled to the encapsulant layer 16 and/or the stiffening layer 18. For example, a protective backskin layer 26 may be formed between the encapsulant layer 16 and the stiffening layer 18, as shown in FIG. 4. Examples of some backskin materials are described in U.S. Pat. No. 5,741,370 (backskins made of thermoplastic olefins, which are capable of being softened, molded, and formed during lamination while still exhibiting thermal creep resistance to satisfy RTI requirements, such as thermoplastic olefins including a first ionomer and a second ionomer) and U.S. Pat. No. 6,320,116 (backskins made of polymeric materials that are subjected to electron beam radiation, which cross-links the polymeric materials without entirely eliminating their thermoplastic properties to provide the polymer with improved thermal creep resistance). The protective backskin layer 26 may be coupled to the open support structure 20 (e.g., as shown in FIG. 4) or coupled to the support layer 24 (e.g., as shown in FIG. 5). An advantage of utilizing a backskin material such as described in U.S. Pat. Nos. 5,741,370 and 6,320,116 is the backskin material's ability to form a very strong bond with aluminum, one exemplary material used for forming the open support structure 20 or the support layer 24.

The stiffening layer 18 provides stiffness to the solar module and allows the module to be formed without the typical glass superstrate and/or perimeter aluminum frame or the need to use other stiffening mechanisms allowing for less costly and/or larger modules. However, embodiments may also include a superstrate and/or a perimeter frame made with typical materials or using other materials. For example, FIGS. 4 and 5 schematically show cross-sectional views of exemplary solar modules having a superstrate 28 according to embodiments of the present invention. The superstrate 28 may be made of glass (e.g., tempered glass) and may have a thickness as used in a conventional module (e.g., 3.2 mm) or the thickness may be thinner than typically used. The superstrate 28 may be made with materials other than glass. For example, the superstrate 28 may be made of a transparent polymer, such as Teflon (e.g., FEP), polycarbonate or polymethyl methacrylate (PMMA). The transparent superstrate 28 may have any thickness, e.g., a thickness between about 30 μm and about 1,000 μm or thicker. Such polymers may also be coated with a thin layer of material, for example to diminish the permeability of these materials to oxygen and water vapor and/or to increase the resistance to scratching, such as SiO₂ or Al₂O₃. Using an alternate cover material may be less costly and/or allow greater optical transmission increasing module efficiency and/or reducing cost per Watt.

Embodiments may include a perimeter frame (not shown), such as an aluminum frame, mounted or secured at the perimeter of the module, or may include a polymer edged module where a polymer layer, e.g., such as used as the superstrate or protective layer, wraps around the edges of the encapsulated photovoltaic cells.

The stiffening layer 18 may be formed with one or more openings 30 in the layer, such as shown in FIG. 6. The opening(s) 30 may be any shape and may be arranged in any manner in the stiffening layer 18. The opening(s) 30 may allow the weight of the stiffening layer 18 to be further reduced without substantially affecting the stiffness of the stiffening layer 18. The opening(s) 30 may be formed in the stiffening layer 18 (e.g., in the open support structure 20 and/or the support layer(s) 24) when the stiffening layer 18 is being formed or after its formation.

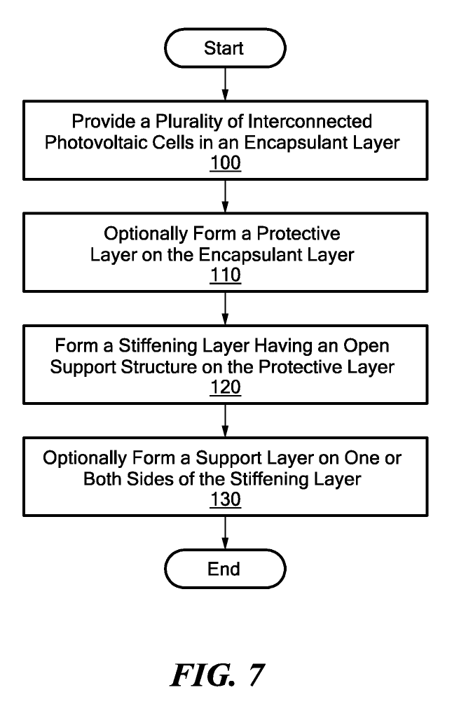

FIG. 7 shows a process of forming a solar module in accordance with illustrative embodiments. Although the following discussion describes various relevant steps of forming a solar module with a stiffening layer, it may not describe all the required steps. Other processing steps may also be performed before, during, and/or after the discussed steps. Such steps, if performed, have been omitted for simplicity. The order of the processing steps may also be varied and/or combined. Accordingly, some steps are not described and shown.

The process begins at step 100, which provides a plurality of interconnected photovoltaic cells 12 in an encapsulant layer 16. The photovoltaic cells 12 may be interconnected to one another and encapsulated in the encapsulant layer 16 by processes well known to those skilled in the art. In step 110, an optional protective backskin layer 26 may be formed on the encapsulant layer 16. In step 120, a stiffening layer 18 having an open support structure 20 may be formed on the protective layer 26, when such layer 26 is used, or may be formed directly on the encapsulant layer 16. In step 130, an optional support layer 24 may be formed on one or both sides of the open support structure 20 before the stiffening layer 18 is coupled to the protective layer 26 or the encapsulant layer 16. For example, the support layer(s) 24 may be laminated to the open support structure 20 or otherwise bonded together to form an integral stiffening layer 18.

Although the above discussion discloses various exemplary embodiments of the invention, it should be apparent that those skilled in the art can make various modifications that will achieve some of the advantages of the invention without departing from the true scope of the invention.

What is claimed is:

1. A solar module comprising:
a plurality of interconnected photovoltaic cells;
an encapsulant layer encapsulating the photovoltaic cells, the encapsulant layer having a first side;
a protective layer coupled to the first side of the encapsulant layer; and
a stiffening layer coupled to the protective layer, the stiffening layer having an open support structure that provides stiffness to the solar module.

2. The solar module of claim 1, wherein the open support structure includes a corrugated structure.

3. The solar module of claim 2, wherein the corrugated structure is a sinusoidal wave shape, a square wave shape, or a trapezoidal wave shape.

4. The solar module of claim 1, wherein the open support structure includes a geometrical structure.

5. The solar module of claim 4, wherein the geometrical structure includes a honeycomb structure.

6. The solar module of claim 1, wherein the open support structure is formed from a metal or metal alloy.

7. The solar module of claim 1, wherein the open support structure is formed from a polymer.

8. The solar module of claim 1, further comprising a transparent superstrate adjacent to a second side of the encapsulant layer.

9. The solar module of claim 1, further comprising a frame disposed at the perimeter of the photovoltaic cells, the encapsulant layer, the protective layer and the stiffening layer for supporting the solar module.

10. The solar module of claim 1, wherein the stiffening layer includes a support layer on at least one side of the open support structure.

11. The solar module of claim 10, wherein the support layer is formed from a metal or metal alloy.

12. The solar module of claim 1, wherein the stiffening layer includes one or more openings formed therein.

13. A method of producing a solar module, the method comprising:
providing a plurality of interconnected photovoltaic cells in an encapsulant layer, the encapsulant layer having a first side;
forming a protective layer on the first side of the encapsulant layer; and
forming a stiffening layer on the protective layer, the stiffening layer having an open support structure that provides stiffness to the solar module.

14. The method of claim 13, wherein the open support structure includes a corrugated structure.

15. The method of claim 14, wherein the corrugated structure is a sinusoidal wave shape, a square wave shape, or a trapezoidal wave shape.

16. The method of claim 13, wherein the open support structure includes a geometrical structure.

17. The method of claim 16, wherein the geometrical structure includes a honeycomb structure.

18. The method of claim 13, wherein the open support structure is formed from a metal or metal alloy.

19. The method of claim 13, wherein the open support structure is formed from a polymer.

20. The method of claim 13, wherein the stiffening layer includes a support layer on at least one side of the open support structure.

21. The method of claim 13, wherein the support layer is formed from a metal or metal alloy.

22. A solar module comprising:
a plurality of interconnected photovoltaic cells;
an encapsulant layer encapsulating the photovoltaic cells, the encapsulant layer having a first side; and
a stiffening layer coupled to the first side of the encapsulant layer, the stiffening layer having an open support structure that provides stiffness to the solar module.

23. The solar module of claim 22, wherein the open support structure includes a corrugated structure.

24. The solar module of claim 22, wherein the open support structure includes a geometrical structure.

25. The solar module of claim 22, wherein the open support structure is formed from a metal or metal alloy.

26. The solar module of claim 22, wherein the open support structure is formed from a polymer.

27. The solar module of claim 22, wherein the stiffening layer includes a support layer on at least one side of the open support structure.

28. The solar module of claim 27, wherein the support layer is formed from a metal or metal alloy.
